(19) United States
(12) Patent Application Publication
(10) Pub. No.: US 2024/0195215 A1
(43) Pub. Date: Jun. 13, 2024

(54) POWER SUPPLY SYSTEM

(71) Applicant: ROHM Co., LTD., Kyoto (JP)

(72) Inventor: Kiyoshi Kondo, Kyoto (JP)

(21) Appl. No.: 18/534,807

(22) Filed: Dec. 11, 2023

(30) Foreign Application Priority Data
Dec. 12, 2022 (JP) 2022-198112

(51) Int. Cl. H02J 9/06; G11C 5/14; H02J 7/00; H02J 7/34

(52) U.S. Cl. CPC H02J 9/068; G11C 5/141; H02J 7/0068; H02J 7/345; H02J 9/061; H02J 2207/50

(57) ABSTRACT

Disclosed herein is a power supply system including a power supply configured to supply power to a load through a supply path, a transforming unit configured to transform a voltage corresponding to an input voltage from the power supply and charge a storage unit, and transform a charge voltage of the storage unit and output an output voltage to the load, and a control unit configured to control an output state of the transforming unit. The control unit controls the output state of the transforming unit such that the transforming unit is able to output the output voltage to the load when the input voltage satisfies a preparation condition, and the supply path is interrupted when the input voltage satisfies an interruption condition after the preparation condition is satisfied.

### CROSS REFERENCE TO RELATED APPLICATIONS

This application claims priority benefit of Japanese Patent Application No. JP 2022-198112 filed in the Japan Patent Office on Dec. 12, 2022. Each of the above-referenced applications is hereby incorporated herein by reference in its entirety.

### BACKGROUND

The present disclosure relates to a power supply system.

The supply of a stable input voltage is necessary for electronic components. When the supply of an input voltage to a storage device such as a solid state drive (SSD) is interrupted, data being stored thereon may be corrupted or lost. The supply of the voltage is demanded to be maintained also after the input voltage from a power supply is interrupted. Technologies for realizing this demand include power loss imminent (PLI), power loss protection (PLP), and other methods.

An example of the related art is disclosed in Japanese Patent Laid-Open No. 2021-5924.

### BRIEF DESCRIPTION OF THE DRAWINGS

FIG. 1A depicts a state in which a power supply system supplies power to a load during a normal time, and FIG. 1B is a diagram of assistance in explaining operation of the power supply system when an abnormality occurs in a power supply;

FIG. 2 is a block diagram depicting an outline of a configuration of a power supply system according to one embodiment of the present disclosure;

FIG. 3 is a flowchart illustrating an example of operation of the power supply system according to one embodiment of the disclosure;

FIG. 4 is a diagram of assistance in explaining an example of a flow of operation of the power supply system according to one embodiment of the present disclosure; and

FIG. 5 is a block diagram of assistance in explaining a power supply system according to a reference technology.

### DETAILED DESCRIPTION

### Outline

An outline of some illustrative embodiments of the present disclosure will be described. This outline describes, in a simplified manner, some concepts of one or a plurality of embodiments as an introduction to the following detailed description for a purpose of basic understanding of the embodiments and does not limit the scope of the invention or the disclosure. This outline is neither a comprehensive outline of all conceivable embodiments nor one intended to identify important elements of all of the embodiments or demarcate the scope of a part of all of aspects. For convenience, “one embodiment” may be used to refer to one embodiment (an example or a modification) or a plurality of embodiments (examples or modifications) disclosed in the present specification.

A power supply system according to one embodiment includes a power supply configured to supply power to a load through a supply path, a transforming unit configured to transform a voltage corresponding to an input voltage from the power supply and charge a storage unit, and transform a charge voltage of the storage unit and output an output voltage to the load, and a control unit configured to control an output state of the transforming unit. The control unit controls the output state of the transforming unit such that the transforming unit is able to output the output voltage to the load when the input voltage satisfies a preparation condition. The supply path is interrupted when the input voltage satisfies an interruption condition after the preparation condition is satisfied.

According to this configuration, it is possible to continue the supply of power more reliably when an abnormality occurs in the input voltage from the power supply.

In one embodiment, the preparation condition may be a condition that the input voltage be lower than a first threshold value. The interruption condition may be a condition that the input voltage be lower than a second threshold value. The second threshold value may be lower than the first threshold value.

In one embodiment, the control unit may control the output state of the transforming unit such that the output voltage of the transforming unit becomes equal to or lower than the first threshold value when the input voltage satisfies the preparation condition.

In one embodiment, the control unit may control the output state of the transforming unit such that the output voltage of the transforming unit rises to a target voltage when the input voltage satisfies the interruption condition.

In one embodiment, the transforming unit may include a step-up converter configured to step up a voltage corresponding to the input voltage and charge the storage unit, and a step-down converter configured to step down the charge voltage of the storage unit and output the output voltage to the load. The step-up converter and the step-down converter may be configured such that one of the step-up converter and the step-down converter operates. The control unit may control the output state of the transforming unit such that the step-down converter operates when the input voltage satisfies the preparation condition.

In one embodiment, the preparation condition may be a condition that the input voltage be higher than the first threshold value. The interruption condition may be a condition that the input voltage be higher than the second threshold value. The second threshold value may be higher than the first threshold value.

### (PLI)

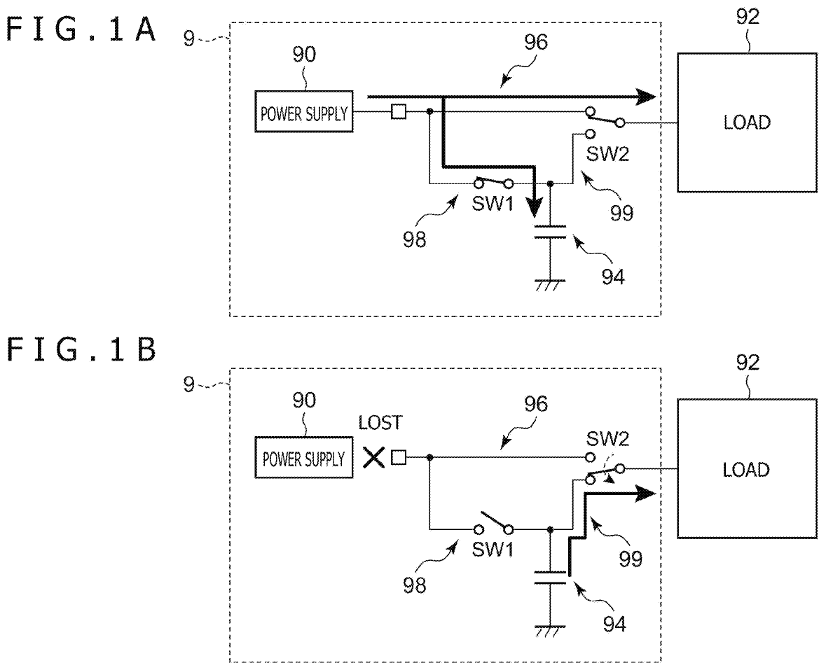

PLI will be described with reference to FIGS. 1A and 1B. PLI is a technology for switching a power source for a load to a backup power supply and thereby continuing operation of a system when a power supply that supplies power to the load is lost. FIG. 1A depicts a state in which a power supply system 9 supplies power to a load 92 during a normal time. FIG. 1B is a diagram of assistance in explaining operation of the power supply system 9 when an abnormality occurs in a power supply 90.

FIG. 1A depicts the power supply system 9 for supplying power to the load 92. The load 92 may be, for example, an SSD or other devices. The power supply system 9 includes a power supply 90, a backup capacitor 94 having one terminal connected to a ground, a supply path 96 connecting the power supply 90 and the load 92 to each other, paths 98 and 99, and switches SW1 and SW2.

The path 98 connects the power supply 90 and another terminal of the capacitor 94 to each other. The path 99 is connected to the path 98, and connects the other terminal of the capacitor 94 and the load 92 to each other. The switch SW1 is disposed on the path 98. In addition, the switch SW2 is disposed so as to connect the supply path 96 or the path 99 to the load 92.

As depicted in FIG. 1A, during the normal time, the switch SW1 is ON, and the switch SW2 connects the supply path 96 to the load 92. Thus, while the power supply 90 supplies power to the load 92 via the supply path 96 and the switch SW2, the power supply 90 can charge the capacitor 94 via the path 98.

Here, suppose that an abnormality (for example, a decrease in the input voltage of the power supply 90, a loss of the power supply 90, a ground short circuit, or other abnormalities) occurs in the power supply 90. At this time, the connection of the switch SW2 is switched from the supply path 96 to the path 99. Consequently, the connection between the power supply 90 and the load 92 is interrupted, and power is supplied from the capacitor 94 to the load 92. Thus, PLI is intended to supply power to the load 92 continuously even in a case where an abnormality occurs in the power supply 90.

It is important in PLI to continue to supply power from a certain power supply as long as possible in order to maintain the operation of the system even at a time of an emergency such as an abnormality in the power supply 90 or other kinds of emergencies. Factors in the emergency include a decrease in the input voltage (a failure in the power supply or an insufficiency of a capability as a power supply source for the load on the system), a loss of the power supply (a failure in the power supply or an interruption of the connection of the power supply due to an abnormality in wiring and connecting lines), a ground short circuit at the input (a short circuit due to foreign matter, an abnormality in a connector, or other abnormalities), a rise in the input voltage (a failure in the power supply or other abnormalities), an increase in the system load (an increase in the load due to a failure in components or other abnormalities), an abnormality in the temperature of an integrated circuit (IC), and other abnormalities.

### Embodiment

A preferred embodiment will hereinafter be described with reference to the drawings. Identical or equivalent constituent elements, members, and processing depicted in each drawing are identified by the same reference signs, and repeated description thereof will be omitted as appropriate. In addition, the embodiment is not restrictive of the disclosure and the invention and is illustrative, and all features described in the embodiment and combinations thereof are not necessarily essential to the disclosure and the invention.

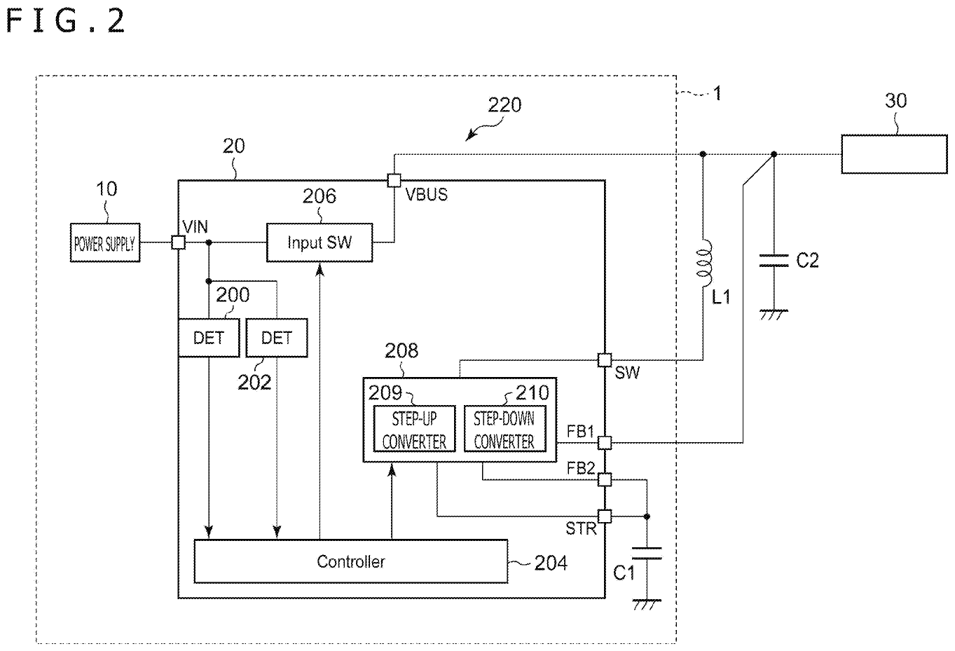

FIG. 2 is a block diagram depicting an outline of a configuration of a power supply system 1 according to one embodiment of the present disclosure. As depicted in FIG. 2, the power supply system 1 is configured to supply power to a load 30. The load 30 may be, for example, an SSD or other devices. The load 30 is connected to a capacitor C2 having one terminal connected to the power supply system 1 and having another terminal connected to a ground.

The power supply system 1 includes a power supply 10 and a control device 20. The power supply 10 supplies power to the load 30 via the control device 20.

The control device 20 transmits power to the load 30 on the basis of an input voltage from the power supply 10. The control device 20 includes a first detecting circuit 200, a second detecting circuit 202, a controller 204, an input switch 206, a transforming unit 208, and a capacitor C1 (storage unit). In addition, the control device 20 is provided with various kinds of pins connected to the outside. Specifically, the control device 20 is provided with a pin VIN connected to the power supply 10, a pin VBUS connected to the load 30, a pin SW connected to the load 30 via an inductor L1, a pin FB1 connected to the load 30, and pins FB2 and STR each connected to one terminal of the capacitor C1.

The input voltage from the power supply 10 is input to the pin VIN. The pin VIN and the pin VBUS are connected to each other via the input switch 206. The input switch 206 is ON during a normal time. During the normal time, the power supply 10 supplies power to the load 30 through a supply path 220 that connects the power supply 10 and the load 30 to each other, more specifically, a path that connects the power supply 10, the pin VIN, the input switch 206, the pin VBUS, and the load 30 to one another.

The first detecting circuit 200 detects that the input voltage from the power supply 10 satisfies a preparation condition. The preparation condition is a condition for the transforming unit 208 to make a preparation for supplying power to the load 30. More specifically, the preparation condition is a condition that the input voltage be lower than a first threshold value. Here, the first threshold value is lower than the input voltage supplied from the power supply 10 during the normal time. The first detecting circuit 200 transmits a result of the detection to the controller 204. For example, when the first detecting circuit 200 detects that the input voltage is lower than the first threshold value, the first detecting circuit 200 may transmit a signal indicating the result to the controller 204.

The second detecting circuit 202 detects that the input voltage from the power supply 10 satisfies an interruption condition. The interruption condition is a condition for interrupting the supply path 220. More specifically, the interruption condition is a condition that the input voltage be lower than a second threshold value. Here, the second threshold value is lower than the first threshold value. The second detecting circuit 202 transmits a result of the detection to the controller 204. For example, when the second detecting circuit 202 detects that the input voltage is lower than the second threshold value, the second detecting circuit 202 may transmit a signal indicating the result to the controller 204.

The transforming unit 208 transforms a voltage corresponding to the input voltage from the power supply 10, and outputs power to the load 30. The transforming unit 208 according to the present embodiment includes a step-up converter 209 and a step-down converter 210. The step-up converter 209 and the step-down converter 210 are configured such that one of the converters operates. Incidentally, during the normal time, the step-up converter 209 operates, and the operation of the step-down converter 210 is stopped.

The step-up converter 209 charges the capacitor C1 during the normal time. Specifically, the step-up converter 209 receives a voltage corresponding to the input voltage through a transmission line (not depicted) from the power supply 10, steps up the voltage, and charges the capacitor C1 through the pin STR. The step-up converter 209 according to the present embodiment receives a feedback related to the charge voltage of the capacitor C1 through the pin FB2, and charges the capacitor C1 according to the feedback.

It is to be noted that, while description in the present embodiment will be made of an example in which a target to be charged by the transforming unit 208 is the capacitor C1, the configuration of the storage unit is not limited to the capacitor. The storage unit may be constituted by various kinds of publicly known components capable of storing various kinds of electric energy.

The step-down converter 210 steps down the charge voltage of the capacitor C1, and outputs an output voltage to the load 30 via the pin SW and the inductor L1. The controller 204 sets a set value of the output voltage of the step-down converter 210 according to the present embodiment. The step-down converter 210 according to the present embodiment outputs the output voltage according to the set value. In addition, the step-down converter 210 receives a feedback of the output voltage (voltage of the pin VBUS) through the pin FB1, and outputs the output voltage on the basis of the feedback.

The controller 204 controls operation in the control device 20. Specifically, the controller 204 controls the operation of the input switch 206 and the transforming unit 208.

The controller 204 can switch a converter to be operated in the transforming unit 208. Specifically, the controller 204 can transmit a signal for switching the converter to be operated to the transforming unit 208. For example, when the first detecting circuit 200 detects that the input voltage satisfies the preparation condition, the controller 204 switches the converter to be operated in the transforming unit 208 from the step-up converter 209 to the step-down converter 210. The step-down converter 210 can thereby step down the charge voltage of the capacitor C1 and output the output voltage to the load 30.

The controller 204 can set the output voltage of the step-down converter 210. Specifically, the controller 204 may transmit a signal for setting the output voltage of the step-down converter 210 to the transforming unit 208. For example, when the first detecting circuit 200 detects that the input voltage satisfies the preparation condition, the controller 204 may set the output voltage lower than the first threshold value. Consequently, when the converter to be operated in the transforming unit 208 is switched from the step-up converter 209 to the step-down converter 210, the input voltage can be made higher than the output voltage. Therefore, at a time of the switching of the converter, the supply of power from the power supply 10 to the load 30 via the supply path 220 is continued, and the supply of power from the step-down converter 210 to the load 30 is suppressed. As a result, unnecessary discharging of the capacitor C1 is suppressed.

The controller 204 may turn the input switch 206 from ON to OFF when the second detecting circuit 202 detects that the input voltage satisfies the interruption condition. The supply path 220 is thereby interrupted, so that power ceases to be supplied from the power supply 10 to the load 30 via the supply path 220. At this time, when the step-down converter 210 is operating in the transforming unit 208, power is supplied from the step-down converter 210 to the load 30.

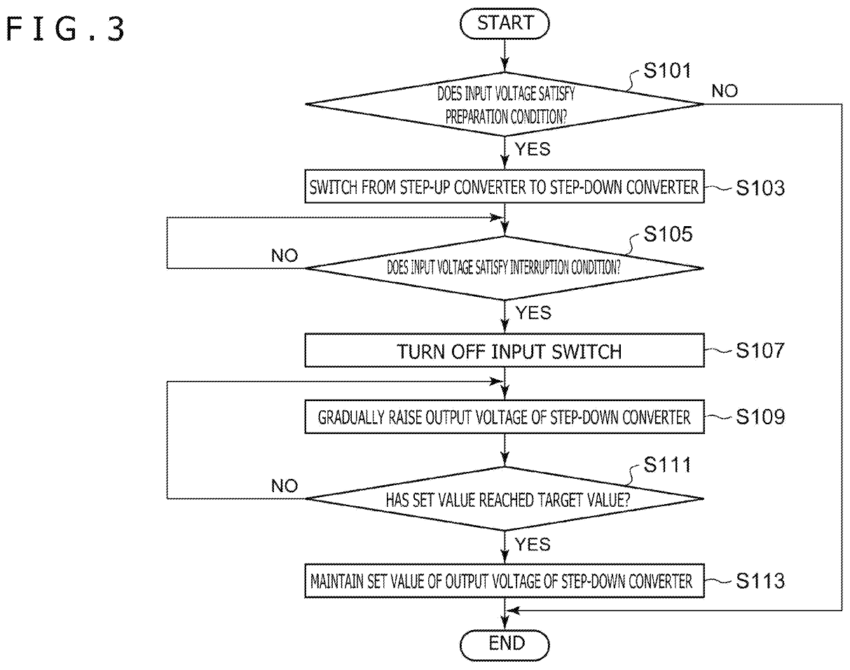

FIG. 3 is a flowchart illustrating an example of operation of the power supply system 1 according to one embodiment of the present disclosure. In the following, the operation of the power supply system 1 will be described along a flowchart depicted in FIG. 3.

First, the first detecting circuit 200 determines whether or not the input voltage from the power supply 10 satisfies the preparation condition (S101). When it is determined that the input voltage does not satisfy the preparation condition, the flowchart depicted in FIG. 3 is ended. When it is determined that the input voltage satisfies the preparation condition, the processing proceeds to S103.

Next, in response to the preparation condition being satisfied by the input voltage in S101, the controller 204 switches the converter to be operated in the transforming unit 208 from the step-up converter 209 to the step-down converter 210 (S103).

Next, the second detecting circuit 202 determines whether or not the input voltage satisfies the interruption condition (S105). When it is determined that the input voltage does not satisfy the interruption condition, the processing of S105 is repeated. When it is determined that the input voltage satisfies the interruption condition, on the other hand, the processing proceeds to S107.

When it is determined in S105 that the input voltage satisfies the interruption condition, the controller 204 turns OFF the input switch 206 (S107). Consequently, the supply path 220 is interrupted, power ceases to be supplied from the power supply 10 to the load 30 via the supply path 220, and power is supplied from the step-down converter 210 to the load 30. Next, the controller 204 sets the set value of the output voltage of the step-down converter 210 such that the output voltage rises gradually (S109). The output voltage of the transforming unit 208 thereby rises gradually.

Next, the controller 204 determines whether or not the set value of the output voltage of the step-down converter 210 has reached a target value (S111). When it is determined that the set value of the output voltage has not reached the target value, the processing returns to S109. When it is determined that the set value of the output voltage has reached the target value, on the other hand, the processing proceeds to S113.

When it is determined in S111 that the set value of the output voltage of the step-down converter 210 has reached the target value, the controller 204 maintains the set value of the output voltage at the target value (S113). When the controller 204 maintains the set value of the output voltage at the target value, the flowchart depicted in FIG. 3 is ended.

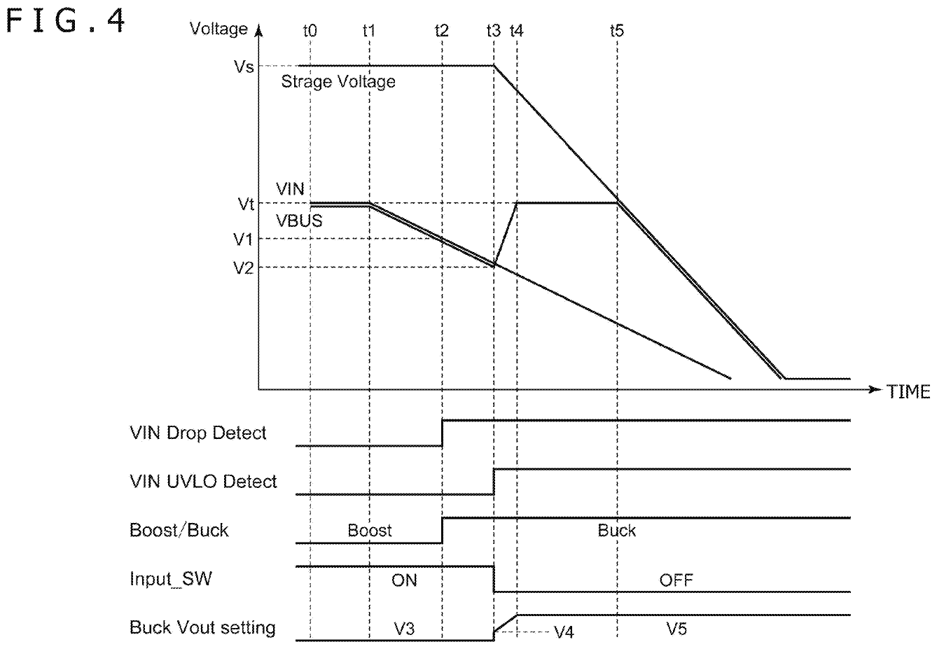

FIG. 4 is a diagram of assistance in explaining an example of a flow of operation of the power supply system 1 according to one embodiment of the present disclosure. An upper side of FIG. 4 depicts, with the passage of time, the charge voltage (Storage Voltage) of the capacitor C1, the input voltage (VIN) from the power supply 10, and the potential (VBUS) of the pin VBUS. In addition, a lower side of FIG. 4 depicts, with the passage of time, a detection result (VIN Drop Detect) of the first detecting circuit 200, a detection result (VIN UVLO Detect) of the second detecting circuit 202, the operating converter (Boost/Buck) in the transforming unit 208, the ON/OFF (Input SW) of the input switch 206, and the set value (Buck Vout setting) of the output voltage which set value is set in the step-down converter 210.

At time t0, the input switch 206 is ON. Therefore, power is supplied from the power supply 10 to the load 30 via the supply path 220. At this time, the input voltage from the power supply 10 is a desired voltage (for example, 12 V). In addition, at time to, the step-up converter 209 is operating in the transforming unit 208. The step-up converter 209 steps up the voltage corresponding to the input voltage from the power supply 10, and charges the capacitor C1 with a voltage Vs.

At time t1, an abnormality occurs in the power supply 10, for example, and the input voltage from the power supply 10 starts to be lowered due to the abnormality. After time further passes, the input voltage falls below a first threshold value V1 (for example, 10.5 V) at time t2. At this time, the first detecting circuit 200 detects that the input voltage satisfies the preparation condition. In response to this detection, the controller 204 switches the converter to be operated in the transforming unit 208 from the step-up converter 209 to the step-down converter 210. The step-down converter 210 thereby becomes able to output the output voltage. At this time, the output voltage of the step-down converter 210 is set at V3 (for example, 9 V) by the controller 204. In addition, at this point in time, the input voltage from the power supply 10 is not lowered to such a degree that the supply source of power needs to be switched from the power supply 10 to the step-down converter 210.

At this time, the set value V3 of the output voltage of the step-down converter 210 is set lower than the first threshold value V1. Therefore, at the time point of time t2, the input voltage from the power supply 10 is higher than the output voltage from the step-down converter 210. Thus, the supply of power from the power supply 10 to the load 30 through the supply path 220 is continued, and the supply of power from the step-down converter 210 to the load 30 is suppressed. Consequently, unnecessary discharging of the capacitor C1 is suppressed.

When time t3 arrives after time further passes from time t2, the input voltage from the power supply 10 falls below a second threshold value V2 (for example, 9.5 V). At this time, the second detecting circuit 202 detects that the input voltage satisfies the interruption condition. According to this detection, the controller 204 switches the input switch 206 from ON to OFF. Consequently, the supply path 220 is interrupted, power ceases to be supplied from the power supply 10 to the load 30 via the supply path 220, and power is supplied from the step-down converter 210 to the load 30. As power is supplied from the step-down converter 210 to the load 30, the capacitor C1 is discharged, and therefore, the charge voltage of the capacitor C1 starts to be lowered. Incidentally, because the output voltage of the step-down converter 210 is lower than the second threshold value, the supply of power from the step-down converter 210 to the load 30 is suppressed until the supply path 220 is interrupted.

In addition, at time t3, the controller 204 sets the output voltage of the step-down converter 210 at a set value V4. The set value V4 may be the same as the second threshold value V2, for example, and may be 9.5 V, for example. Thereafter, the controller 204 gradually raises the set value such that the output voltage of the step-down converter 210 rises to a target voltage Vt (for example, 12 V). Accordingly, the voltage of the pin VBUS rises gradually.

When time t4 arrives, the set value of the output voltage reaches V5. Accordingly, the output voltage of the step-down converter 210 reaches the target voltage Vt. Thereafter, the set value of the output voltage is maintained, and the voltage of the pin VBUS is also maintained at Vt. When the charge voltage of the capacitor C1 becomes equal to or lower than Vt at time t5, the voltage of the pin VBUS also becomes equal to or lower than Vt accordingly. Thus, in the present example, even in a case where an abnormality occurs in the power supply 10, the supply source of power can be smoothly switched from the power supply 10 to the step-down converter 210, and a desired voltage can continue to be supplied to the load 30 from time t4 to t5, in particular.

### Reference Technology

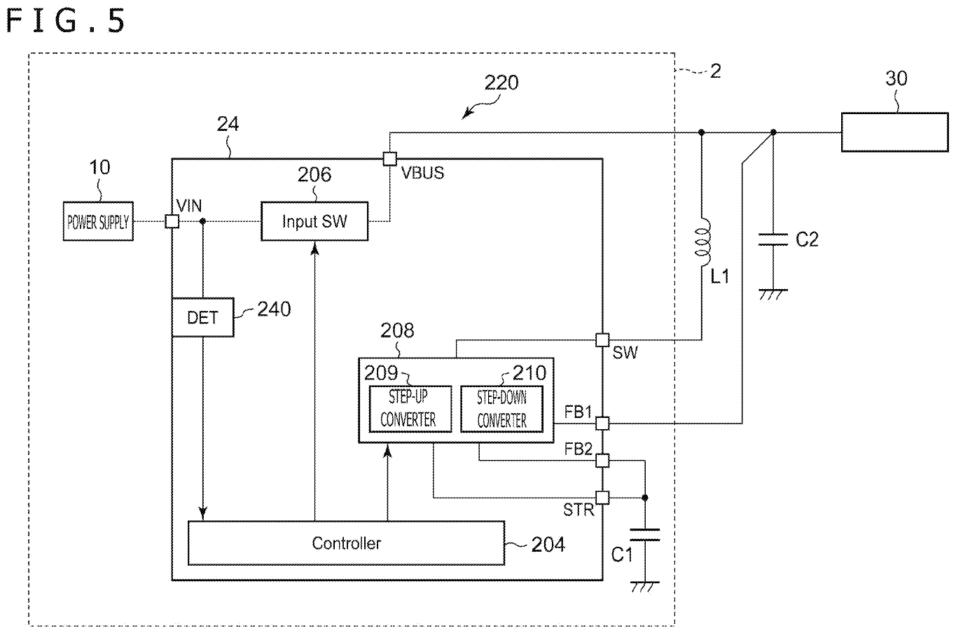

FIG. 5 is a block diagram of assistance in explaining a power supply system 2 according to a reference technology. In FIG. 5, configurations having substantially the same functions as the configurations depicted in FIG. 2 are identified by the same reference signs, and description thereof will be omitted as appropriate.

The power supply system 2 according to the reference technology includes the power supply 10 and a control device 24. The control device 24 according to the reference technology includes a detecting circuit 240 in place of the first detecting circuit 200 and the second detecting circuit 202 of the control device 20 according to the foregoing embodiment.

In the following, description will be made of an example in which the power supply 10 is lost while the power supply 10 is supplying power to the load 30 via the supply path 220. The power supply system 2 according to the reference technology operates as follows. First, the detecting circuit 240 detects a loss of the power supply 10 on the basis of the input voltage or other parameters. The controller 204 turns OFF the input switch 206 on the basis of the detection. Consequently, the supply path 220 is interrupted. Next, the controller 204 switches the converter to be operated in the transforming unit 208 from the step-up converter 209 to the step-down converter 210. Consequently, power is supplied from the step-down converter 210 to the load 30.

At this time, when the switching from the step-up converter 209 to the step-down converter 210 is slow, the power supplied to the load 30 is lowered, and the operation of the load 30 may be stopped. In a case where the load 30 is an SSD, for example, data stored on the SSD may be lost.

In contrast, in the power supply system 1 depicted in FIG. 2, before the input voltage satisfies the interruption condition, the controller 204 can control the output state of the transforming unit 208 in advance (specifically when the input voltage from the power supply 10 satisfies the preparation condition) such that the step-down converter 210 can supply the output voltage to the load 30. When the input voltage thereafter satisfies the interruption condition, the supply path 220 is interrupted, and power is supplied from the step-down converter 210 to the load 30.

Thus, according to the power supply system 1, the supply source of power to the load 30 is switched from the power supply 10 to the step-down converter 210 on the basis of detection in two stages, that is, detection of the preparation condition and detection of the interruption condition. Therefore, according to the power supply system 1, a margin is provided for a time of switching from the step-up converter 209 to the step-down converter 210 as compared with the power supply system 2 according to the reference technology. Therefore, according to the power supply system 1, it is possible to supply power to the load 30 continuously, and reduce a risk of stopping the operation of the load 30.

### Modification

Description has been made of an example in which the power supply system 1 described with reference to FIG. 2 switches the supply source of power to the load 30 mainly when the input voltage from the power supply 10 becomes lower than a specified voltage. Without being limited to this, the power supply system 1 may be configured to switch the supply source when the input voltage becomes too high.

Specifically, the preparation condition may be a condition that the input voltage be higher than the first threshold value. Incidentally, this first threshold value is higher than the input voltage during the normal time. In addition, the interruption condition may be a condition that the input voltage be higher than the second threshold value. Further, the second threshold value may be higher than the first threshold value.

An example of operation of the power supply system 1 in this case will be described. First, the first detecting circuit 200 detects that the input voltage is higher than the first threshold value. In response to this detection, the controller 204 switches the converter to be operated in the transforming unit 208 from the step-up converter 209 to the step-down converter 210. Next, the second detecting circuit 202 detects that the input voltage is higher than the second threshold value. In response to this detection, the controller 204 turns OFF the input switch 206. Consequently, the source of supply to the load 30 is switched from the power supply 10 to the step-down converter 210.

According to the power supply system 1, even in a case where the input from the power supply 10 becomes too high due to a certain abnormality, switching can be performed from the step-up converter 209 to the step-down converter 210 with a time margin by detecting the input voltage in two stages. It is consequently possible to continue the supply of power more reliably when an abnormality occurs in the input voltage from the power supply 10.

### Supplementary Notes

The technology disclosed in the present specification can be recognized as follows in one aspect.

### Item 1

A power supply system including:
a power supply configured to supply power to a load through a supply path;
a transforming unit configured to transform a voltage corresponding to an input voltage from the power supply and charge a storage unit, and transform a charge voltage of the storage unit and output an output voltage to the load; and
a control unit configured to control an output state of the transforming unit,
in which the control unit controls the output state of the transforming unit such that the transforming unit is able to output the output voltage to the load when the input voltage satisfies a preparation condition, and
the supply path is interrupted when the input voltage satisfies an interruption condition after the preparation condition is satisfied.

### Item 2

The power supply system according to Item 1, in which
the preparation condition is a condition that the input voltage be lower than a first threshold value,
the interruption condition is a condition that the input voltage be lower than a second threshold value, and
the second threshold value is lower than the first threshold value.

### Item 3

The power supply system according to Item 2, in which
the control unit controls the output state of the transforming unit such that the output voltage of the transforming unit is equal to or lower than the first threshold value when the input voltage satisfies the preparation condition.

### Item 4

The power supply system according to Item 3, in which
the control unit controls the output state of the transforming unit such that the output voltage of the transforming unit rises to a target voltage when the input voltage satisfies the interruption condition.

### Item 5

The power supply system according to any one of Items 1 to 4, in which
the transforming unit includes a step-up converter configured to step up a voltage corresponding to the input voltage and charge the storage unit, and a step-down converter configured to step down the charge voltage of the storage unit and output the output voltage to the load,
the step-up converter and the step-down converter are configured such that one of the step-up converter and the step-down converter operates, and
the control unit controls the output state of the transforming unit such that the step-down converter operates when the input voltage satisfies the preparation condition.

### Item 6

The power supply system according to Item 1, in which
the preparation condition is a condition that the input voltage be higher than the first threshold value,
the interruption condition is a condition that the input voltage be higher than the second threshold value, and
the second threshold value is higher than the first threshold value.

### Supplement

The present disclosure has been described above on the basis of embodiments thereof. The embodiments are illustrative, and it is to be understood by those skilled in the art that combinations of constituent elements and processing processes of the embodiments are susceptible of various modifications and that such modifications also fall within the scope of the present invention.

According to the present disclosure, it is possible to provide a power supply system for continuing the supply of power more reliably when an abnormality occurs in an input voltage from a power supply.

What is claimed is:

1. A power supply system comprising:
a power supply configured to supply power to a load through a supply path;
a transforming unit configured to transform a voltage corresponding to an input voltage from the power supply and charge a storage unit, and transform a charge voltage of the storage unit and output an output voltage to the load; and
a control unit configured to control an output state of the transforming unit,
wherein the control unit controls the output state of the transforming unit such that the transforming unit is able to output the output voltage to the load when the input voltage satisfies a preparation condition, and
the supply path is interrupted when the input voltage satisfies an interruption condition after the preparation condition is satisfied.

2. The power supply system according to claim 1, wherein
the preparation condition is a condition that the input voltage be lower than a first threshold value,
the interruption condition is a condition that the input voltage be lower than a second threshold value, and
the second threshold value is lower than the first threshold value.

3. The power supply system according to claim 2, wherein
the control unit controls the output state of the transforming unit such that the output voltage of the transforming unit is equal to or lower than the first threshold value when the input voltage satisfies the preparation condition.

4. The power supply system according to claim 3, wherein
the control unit controls the output state of the transforming unit such that the output voltage of the transforming unit rises to a target voltage when the input voltage satisfies the interruption condition.

5. The power supply system according to claim 1, wherein
the transforming unit includes a step-up converter configured to step up a voltage corresponding to the input voltage and charge the storage unit, and a step-down converter configured to step down the charge voltage of the storage unit and output the output voltage to the load,
the step-up converter and the step-down converter are configured such that one of the step-up converter and the step-down converter operates, and
the control unit controls the output state of the transforming unit such that the step-down converter operates when the input voltage satisfies the preparation condition.

6. The power supply system according to claim 1, wherein
the preparation condition is a condition that the input voltage be higher than the first threshold value,
the interruption condition is a condition that the input voltage be higher than the second threshold value, and
the second threshold value is higher than the first threshold value.
